(19) United States
(12) Patent Application Publication
(10) Pub. No.: US 2013/0335929 A1
(43) Pub. Date: Dec. 19, 2013

(54) ELECTRONIC DEVICE AND METHOD WITH FLEXIBLE DISPLAY

(71) Applicant: Alberto R. Cavallaro, Northbrook, IL (US)

(72) Inventor: Alberto R. Cavallaro, Northbrook, IL (US)

(73) Assignee: MOTOROLA MOBILITY, INC., Libertyville, IL (US)

(21) Appl. No.: 13/526,673

(22) Filed: Jun. 19, 2012

(51) Int. Cl. H05K 1/18; H01R 43/00

(52) U.S. Cl. 361/749; 29/825

(57) ABSTRACT

An electronic device (200) and method (300) with flexible display is disclosed. The method (300) can include: providing (310) a flexible chassis module including a front portion having a channel and a rear portion; inserting (320) a display module in the channel; and coupling (33)0) an electronics module to the rear portion of the flexible chassis module. This method allows flexing of an electronic device with a flexible display for curved viewing, if desired, or bending with minimal stress.

### BACKGROUND

1. Field

The present disclosure relates to a method and device with a flexible display.

2. Introduction

Devices with a flexible display are gaining interest. Some technologies involved in building flexible displays include electronic ink, Gyricon, and OLED.

Electronic paper displays which can be rolled up have been developed by E Ink. E Ink refers to it as electrophoretic technology. At the Consumer Electronics Show (CES) in 2006, Philips showed a rollable display prototype.

Some flexible displays use flexible Organic LED display technology. There is a major interest and desire to commercialize flexible displays, for many use cases, such as in gaming, enterprise applications, tablets, electronic devices, wristwatches and the like. As is known, in use, electronic devices are often subjected to harsh environments. Unfortunately, they are dropped on a hard surface, exposed to water, bent or stressed and crushed. For example, user's place electronic devices, such as cell phones, in their back pants pocket and then sit on them. This undesirable behavior can cause high field returns, due to damage to displays. They are stressed or bent, and the display are cracked or damaged. It would be considered an improvement in the art, if an enhanced A robust electronic method and device with a flexible display, would be considered an improvement in the art.

### BRIEF DESCRIPTION OF THE DRAWINGS

In order to describe the manner in which the above-recited and other advantages and features of the disclosure can be obtained, a more particular description of the disclosure briefly described above will be rendered by reference to specific embodiments thereof which are illustrated in the appended drawings. Understanding that these drawings depict only typical embodiments of the disclosure and are not therefore to be considered to be limiting of its scope, the disclosure will be described and explained with additional specificity and detail through the use of the accompanying drawings in which:

FIG. 1 is an exemplary block diagram of a communication system with an electronic device 120 with flexible display, according to one embodiment.

FIG. 2 is an exemplary block diagram of an electronic device according to one embodiment.

FIG. 3 is an exemplary block diagram of a method with a flexible display according to one embodiment.

FIG. 4 is a partial view of an exemplary electronic device with a flexible display, shown in a curved or flexed position, according to one embodiment.

FIG. 5 is a partial view of an exemplary electronic device with a flexible display, showing a segment of a flexible chassis module, according to one embodiment.

FIG. 6 is a partial view of an exemplary electronic device with a flexible display, showing a plurality of segments of a flexible chassis module, each segment including edge structures configured to limit angular movement of the flexible chassis module, as shown in a flexed or curved position, according to one embodiment.

FIG. 7 is a partial view of an exemplary electronic device with a flexible display, showing a plurality of segments of a flexible chassis module, each segment including edge structures configured to limit angular movement of the flexible chassis module, as shown in a flat position 728 and a flexed position 730, according to one embodiment.

FIG. 8 is an exemplary electronic device in the form of a wearable device, it shows a housing skin shown in phantom covering most of the components except the display would be exposed, according to one embodiment.

### DETAILED DESCRIPTION

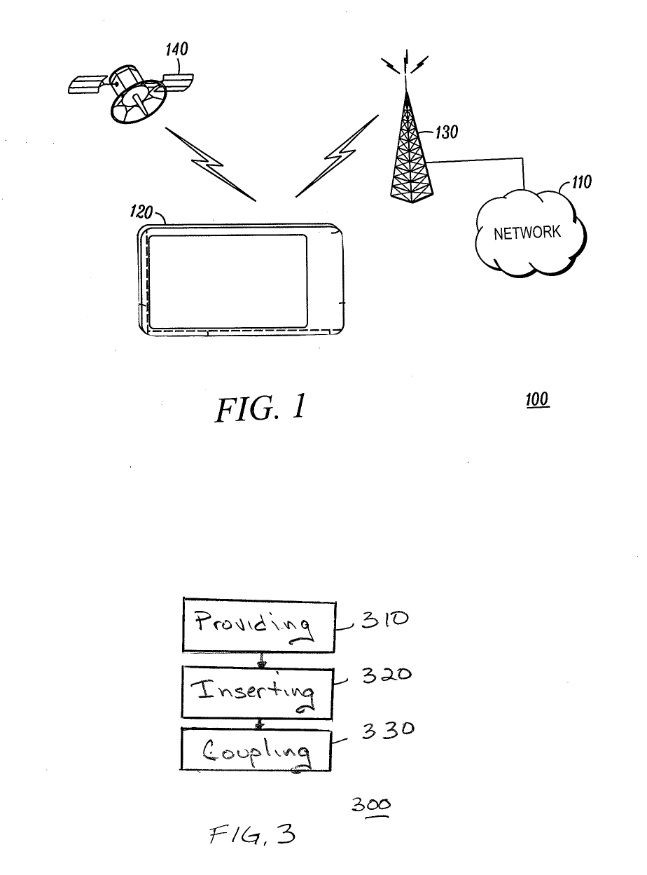

FIG. 1 is an exemplary block diagram of a system 100 according to one embodiment. The system 100 can include a network 110, a terminal 120, and a base station 130. The terminal 120 may be a wireless communication device, such as a wireless telephone, a cellular telephone, a personal digital assistant, a pager, a personal computer, a tablet, a selective call receiver, or any other device that is capable of sending and receiving communication signals on a network including a wireless network. The network 110 may include any type of network that is capable of sending and receiving signals, such as wireless signals. For example, the network 110 may include a wireless telecommunications network, a cellular telephone network, a Time Division Multiple Access (TDMA) network, a Code Division Multiple Access (CDMA) network, Global System for Mobile Communications (GSM), a Third Generation (3G) network, a Fourth Generation (4G) network, a satellite communications network, and other like communications systems. More generally, network 110 may include a Wide Area Network (WAN), a Local Area Network (LAN) and/or a Personal Area Network (PAN). Furthermore, the network 110 may include more than one network and may include a plurality of different types of networks. Thus, the network 110 may include a plurality of data networks, a plurality of telecommunications networks, a combination of data and telecommunications networks and other like communication systems capable of sending and receiving communication signals. In operation, the terminal 120 (also referred to as electronic device 120) can communicate with the network 110 and with other devices on the network 110 by sending and receiving wireless signals via the base station 130, which may also comprise local area, and/or personal area access points. The terminal 120 is shown being in communication with a global positioning system (GPS) 140 satellite, global navigation satellite system (GNSS) or the like, for position sensing and determination.

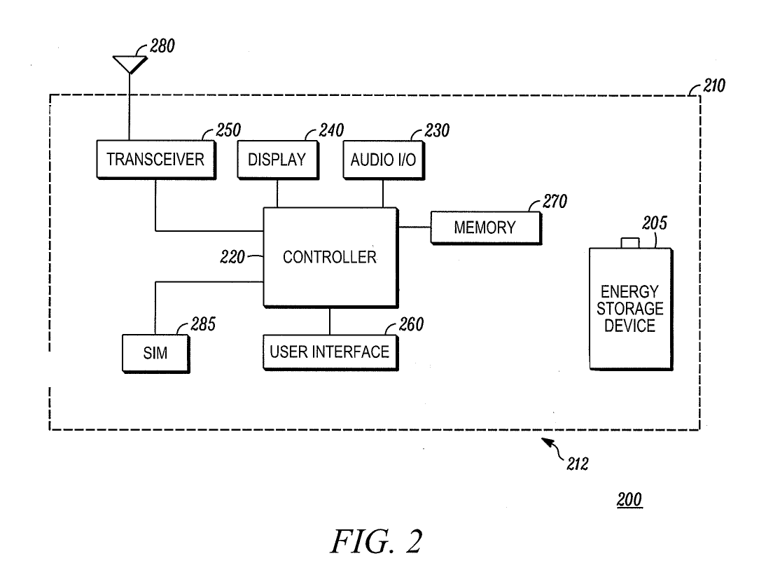

FIG. 2 is an exemplary block diagram of an electronic device or wireless communication device 200, configured with an energy storage device, battery or module 205, such as in the terminal 120, for example. The wireless communication device 200 can include a housing 210, a controller 220 coupled to the housing 210, audio input and output circuitry 230 coupled to the housing 210, a display 240 coupled to the housing 210, a transceiver 250 coupled to the housing 210, a user interface 260 coupled to the housing 210, a memory 270 coupled to the housing 210, an antenna 280 coupled to the housing 210 and the transceiver 250, and a removable subscriber module 285 coupled to the controller 220.

The display 240 can be a liquid crystal display (LCD), a light emitting diode (LED) display, a plasma display, a touch screen display or any other means for displaying information. In one embodiment, the display 240 is a flexible display. The display technology can include flexible Organic LED display technology, electronic ink, Gyricon, and OLED electrophoretic technology, as should be understood by those skilled in the art.

The transceiver 250 may include a transmitter and/or a receiver. The audio input and output circuitry 230 can include a microphone, a speaker, a transducer, or any other audio input and output circuitry. The user interface 260 can include a keypad, buttons, a touch screen or pad, a joystick, an additional display, or any other device useful for providing an interface between a user and an electronic device. The memory 270 may include a random access memory, a read only memory, an optical memory or any other memory that can be coupled to a wireless communication device.

A block diagram of an electronic method with flexible display, is shown in FIG. 3. In its simplest form, the method 300 includes the steps of: providing 310 a flexible chassis module including a front portion having a channel and a rear portion; inserting 320 a display module in the channel; and coupling 330 an electronics module to the rear portion of the flexible chassis module. This method allows flexing of an electronic device with a flexible display for curved viewing, if desired, or bending with minimal stress and potential damage.

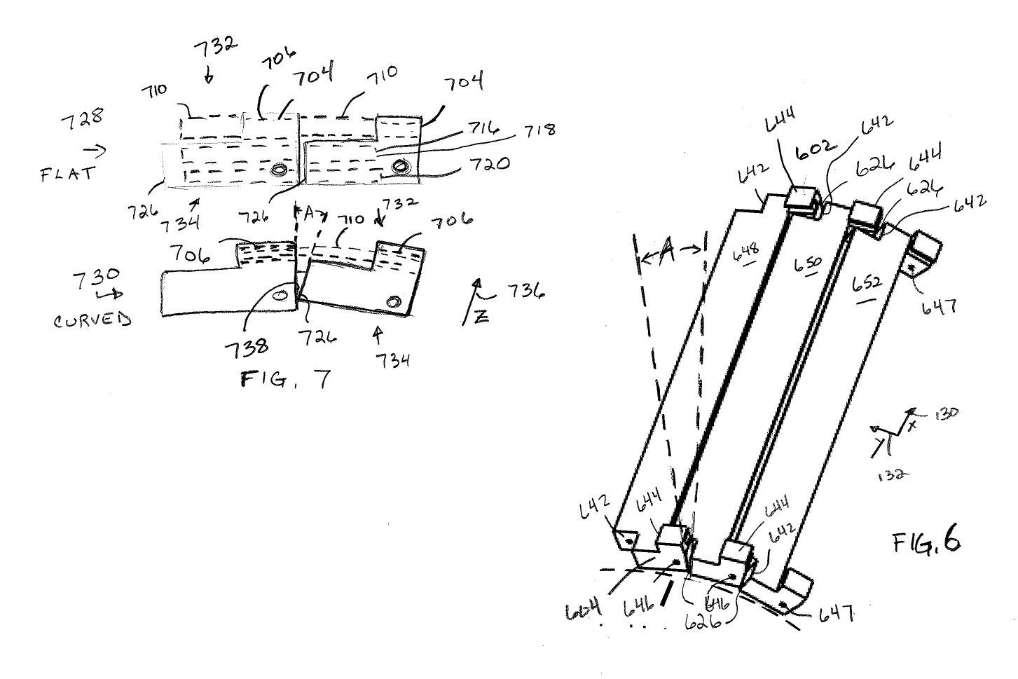

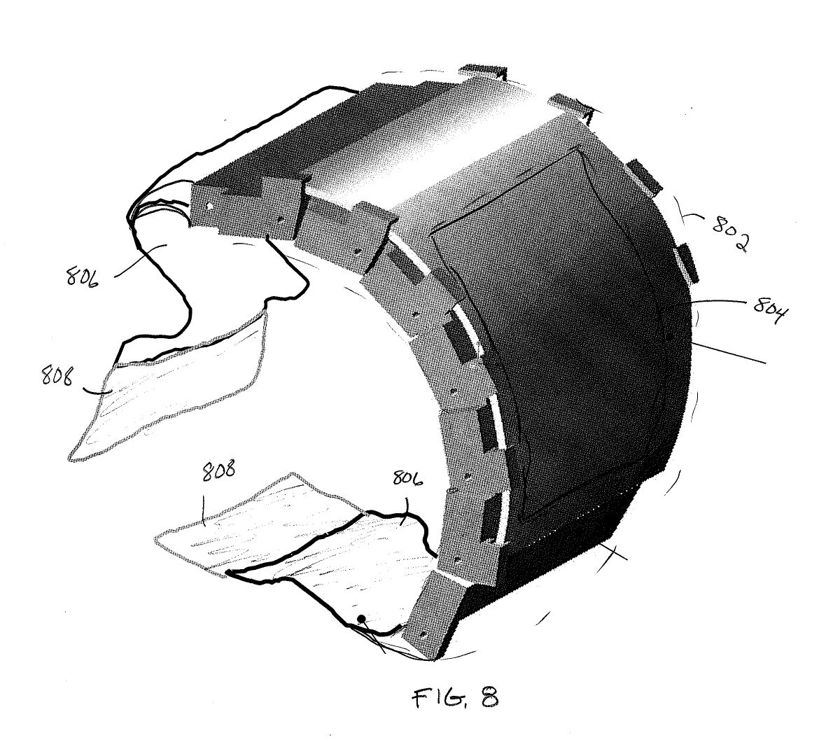

Advantageously, the flexible chassis module can be configured to resist excessive angular rotation. For example, the flexible chassis module 700 in one embodiment, can be configured to allow components, such as a display module 710 and an electronic module 716, to float and allow a certain threshold amount of bending, as shown in FIG. 7. This could help to minimize field returns of damaged electronic devices. The inserted display module in the channel in step 320, can provide stress relief to the display module 710, as shown in the flexed position 730 in FIG. 7, whereas prior art devices can readily fail upon bending. An adhesive can be used to bond the display module 410 to and in the channel 406, for a secure connection and providing a floating connection.

The method 300 can provide flexing along an x-axis 130, and can be oriented to flex along a y-axis.

In one embodiment, the flexible chassis module can include providing a narrow profile structure with a front display module and the rear portion including the electronics module including a flexible printed circuit board and an energy storage device. Consumers embrace narrow profile electronic devices.

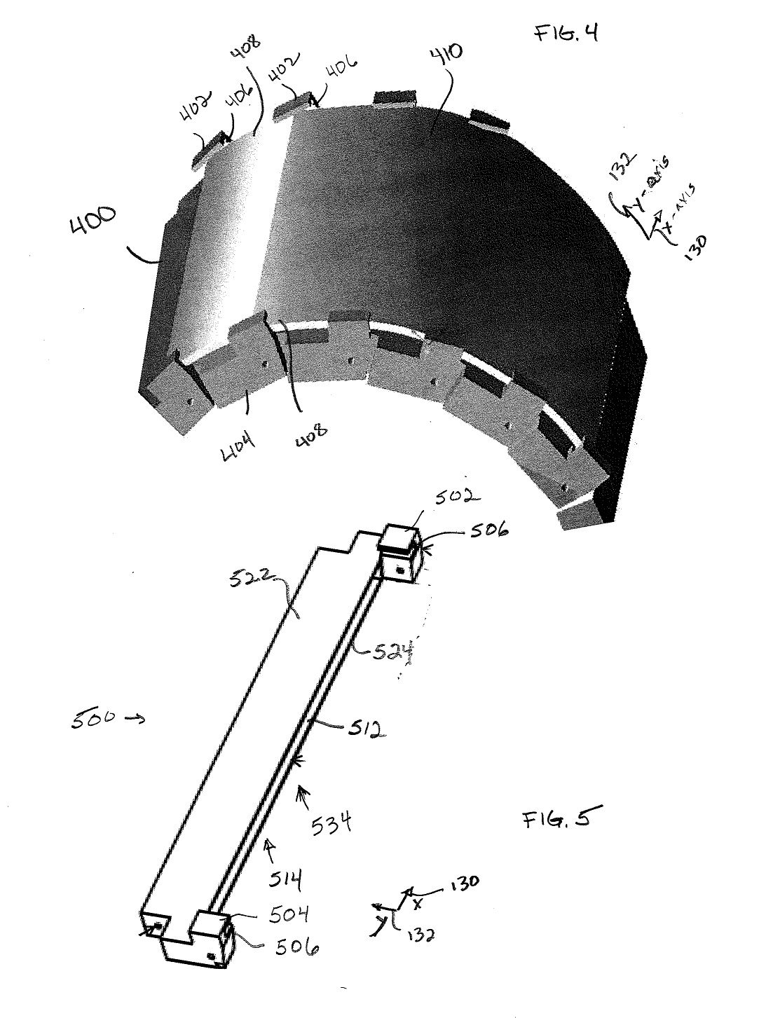

Referring to FIG. 4, the flexible chassis module 400 includes providing edge structures 402 and 404 with each having a channel 406 complementarily configured to receive a portion 408 of an outer periphery of the display module 410.

Returning to the coupling step 330, it can include providing a cavity 512 adapted and configured to receive the electronics module in the rear portion 514 of the flexible chassis module 400, the rear portion 514 can further include the electronics module 716 including a flexible printed circuit board 718 and an energy storage device 720 520. This structure helps to provide a narrow profile electronic device. The cavity 512 is defined by an upper planar frame 522 and a lower planar frame 524, to receive and allow the electronic module 516 to float therein. These frames 522 and 524 provide structural robustness and heat spreaders, for dissipating heat from the electronic module 516.

The method 300 can further include providing a housing substantially covering the flexible chassis module and electronics module and substantially free from covering the flexible display. Thus, one embodiment, a user would substantially only see a housing with a display, such as an electronic device like a wireless communication device, a cell phone or tablet, in FIG. 1 or wearable device in FIG. 8.

As best shown in FIG. 6, in one arrangement, the flexible chassis module 600 includes edge structures 602 and 604 configured to limit angular movement of the flexible chassis module via a stopper structure 626. The limited angular movement provided by the stopper structure 626 can vary widely. In one embodiment, the limited angular movement is less than 30 degrees, preferably ranging from about 20 degrees to about 10 degrees, for a fine and gradual curvature, and most preferably about 15 degrees, as shown at angle A in FIGS. 6 and 7.

As shown in FIG. 7, the flexible chassis module 700 provides an unflexed position 728 and a flexed position 730 or curved orientation. The edge structures 704, each with a stopper structure 726, are configured to limit angular movement of the flexible chassis module 700 and components therein, when moved to the flexed position 730. The curved orientation is shown with the front face being convex. As should be understood, the flexible chassis module 700 can also curve in a concave orientation and be limited with an angular range, as detailed herein. Allowing concave and convex flexibility, can provide enhanced reliability for electronic devices, including and not limited to cell phones, tablets and wearable devices.

Exemplary embodiments of an electronic device 200 with a flexible chassis module are shown in FIGS. 4-8. The identifying numbers for FIGS. 4-7 are similar, and will not each be discussed in detail for each figure. For example, FIG. 4 starts with identifier 400, FIG. 5 with identifier 500, FIG. 6 with identifier 600 and FIG. 7 with identifier 700.

The electronic device 200 can include: a flexible chassis module 700 including a front portion 732 having a channel 706 (shown in dashed line) and a rear portion 734; a display module 710 (shown in dashed line) connected to and partially received in the channel 706; and an electronics module 716 coupled to the rear portion 734 of the flexible chassis module 700.

In one embodiment as shown in FIG. 7, the flexible chassis module includes a mechanism configured to resist rotation of segments at a predetermined angle, and thus minimize or limit free movement of segments unintended by a user. For example, the flexible chassis module 700 can be configured to allow a display module 710 and the electronic module 716 to float and allow a certain threshold amount of bending, as shown in FIG. 7. In more detail, upon bending, the display module 710 in channel 706 and electronic module 716 in cavity 712 are decoupled from and float in the flexible chassis module 400, thus being able to withstand a certain threshold amount of stress.

Stated differently, the flexible chassis module 700 is configured to be reinforced to limit undesirable bending past a certain threshold amount. In this case, the display module 710 and the structure of the flexible chassis module 700 are decoupled due to the floating construction, and the display module 710 floats in the flexible chassis module 700.

In one arrangement, the flexible chassis module 700 includes a narrow profile structure along a z-axis 736 with a front display module 710 and the rear portion 734 including the electronics module 716 (shown in dashed line) including a flexible printed circuit board 718 and an energy storage device 720 (shown in dashed line). Consumers desire narrow profile and robust electronic devices.

As illustrated in FIGS. 4 and 5, the flexible chassis module 500 includes edge structures 502 and 504 with each having a channel 506 facing inwardly and being complementarily configured to receive a portion 408 of an outer periphery of the display module 410 and the rear portion 534 of the flexible chassis module 500 has a cavity 512 complementarily configured to receive the electronics module 716 (in FIG. 7). Advantageously, this structure provides a narrow profile, modularity, robustness and an easy to manufacture and assemble electronic device.

In a preferred arrangement, a housing 210 substantially covering the flexible chassis module and electronics module and substantially free from covering the flexible display is provided.

As best illustrated in FIGS. 6 and 7, the flexible chassis module 700 can include edge structures 704 configured to limit angular movement of the flexible chassis module, as shown as flexed position 730. The edge structures 704 each have a stopper structure 726 configured to limit an angular movement of the flexible chassis module when moved to the flexed position 730, limited to angle A in FIG. 7. Advantageously, this is accomplished by each adjacent individual segment having the stopper structure 726 being closely located to an adjacent segment stopper structure 738, to limit angular movement.

Also as illustrated in FIG. 6, in a preferred embodiment, the edge structures 602 and 604 include a détente mechanism 642 or female section, such as in the form of a rectangular or square geometry or substantially a cut out geometry, complementarily configured to interconnect with a male section 644 of an adjacent segment. FIG. 6 shows a first segment 648, second segment 650 and third segment 652 connected with pins 646 in apertures 647, to allow a curved chassis construction. As understood, various numbers of segments can be provided, depending on the amount of curvature desired. Also various cut out geometries can be utilized, as should be understood. In one embodiment as shown in FIG. 7, the flexible chassis module includes a detent mechanism 642 configured to resist rotation of segments at a specific angle. In one embodiment, the mechanism is provided to resist rotation of segments at specific angles, such as, but not limited to, concave and convex orientations, and thus minimize or limit unwanted bending movement of segments or links unintended by a user.

For example, the flexible chassis module 700 is configured to allow a display module 710 and the electronic module 716 to float and allow a certain threshold amount of bending. In more detail, upon a threshold bending, the display module 710 in channel 706 and electronic module 716 in cavity 712 are decoupled in a sense and float in the flexible chassis module 400 to be able to withstand a certain threshold stress. This construction can provide stress relief to the display module 710, as shown in the flexed position 730 in FIG. 7, whereas prior art devices can readily fail upon bending. Stated differently, the flexible chassis modules shown in FIGS. 4-7, are configured to be reinforced to limit undesirable bending past a threshold amount. In flexed position 730, the display module 710 and flexible chassis module 700 can be thought of as being decoupled in a sense, and the display module 710 floats in the channel 706 of the flexible chassis module 700. In this case, most of the stress is on the module 700 and less on the display module 710, thus allowing the display module 710 to float in the flexible chassis module 700, for enhanced resilience for the display module 710. FIG. 8 is an exemplary electronic device in the form of a wearable device 800, a housing skin 802 shown in phantom covers most of the components except the display 804 can be exposed, according to one embodiment. This embodiment can further include a band 806, and connecting mechanism 808, as should be understood. The device 120 described herein has many potential use cases, including but not limited to: wearable devices, consumer use in gaming, newspapers, ebooks, electronic poster boards and the like; use in wireless communication devices, such as cell phones, tablets such as a Zoom by Motorola and an iPad by Apple; and enterprise use for technical drawings, such as schematics, mechanical and architectural drawings, service industry and the like.

The device 210 and 200 and method are preferably implemented on a programmed processor. However, the controllers, flowcharts, and modules may also be implemented on a general purpose or special purpose computer, a programmed microprocessor or microcontroller and peripheral integrated circuit elements, an integrated circuit, a hardware electronic or logic circuit such as a discrete element circuit, a programmable logic device, or the like. In general, any device on which resides a finite state machine capable of implementing the flowcharts shown in the figures may be used to implement the processor functions of this disclosure.

While this disclosure has been described with specific embodiments thereof, it is evident that many alternatives, modifications, and variations will be apparent to those skilled in the art. For example, various components of the embodiments may be interchanged, added, or substituted in the other embodiments. Also, all of the elements of each figure are not necessary for operation of the disclosed embodiments. For example, one of ordinary skill in the art of the disclosed embodiments would be enabled to make and use the teachings of the disclosure by simply employing the elements of the independent claims. Accordingly, the preferred embodiments of the disclosure as set forth herein are intended to be illustrative, not limiting. Various changes may be made without departing from the spirit and scope of the disclosure. In this document, relational terms such as “first,” “second,” and the like may be used solely to distinguish one entity or action from another entity or action without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a,” “an,” or the like does not, without more constraints, preclude the existence of additional identical elements in the process, method, article, or apparatus that comprises the element. Also, the term “another” is defined as at least a second or more. The terms “including,” “having,” and the like, as used herein, are defined as “comprising.”

We claim:

1. An electronic method, comprising:
providing a flexible chassis module including a front portion having a channel and a rear portion;
inserting a display module in the channel; and
coupling an electronics module to the rear portion of the flexible chassis module.

2. The electronic method of claim 1, wherein the flexible chassis module includes providing a narrow profile structure with a front display module and the rear portion including the electronics module including a flexible printed circuit board and an energy storage device.

3. The electronic method of claim 1, wherein the flexible chassis module includes providing edge structures with each having a channel complementarily configured to receive a portion of the display module.

4. The electronic method of claim 1, wherein the flexible chassis module includes providing edge structures with each having a channel complementarily configured to receive a portion of an outer periphery of the display module.

5. The electronic method of claim 1, wherein the coupling step includes providing a cavity for receiving the electronics module in the rear portion of the flexible chassis module.

6. The electronic method of claim 1, wherein the coupling step includes providing a cavity for receiving the electronics module in the rear portion of the flexible chassis module, the rear portion including the electronics module including a flexible printed circuit board and an energy storage device.

7. The electronic method of claim 1, further comprising providing a housing substantially covering the flexible chassis module and electronics module.

8. The electronic method of claim 1, further comprising providing a housing substantially covering the flexible chassis module and electronics module and substantially free from covering the flexible display.

9. The electronic method of claim 1, wherein the flexible chassis module includes edge structures configured to limit angular movement of the flexible chassis module.

10. The electronic method of claim 1, wherein the flexible chassis module includes edge structures configured to limit angular movement of the flexible chassis module via a stopper structure.

11. The electronic method of claim 1, wherein the flexible chassis module provides an unflexed position and a flexed position.

12. The electronic method of claim 1, wherein the flexible chassis module provides an unflexed position and a flexed position, the flexible chassis module further includes edge structures each with a stopper structure configured to limit an angular movement of the flexible chassis module when moved to the flexed position.

13. An electronic device, comprising:
a flexible chassis module including a front portion having a channel and a rear portion;
a display module connected to and partially received in the channel; and
an electronics module coupled to the rear portion of the flexible chassis module.

14. The electronic device of claim 13, wherein the flexible chassis module includes a narrow profile structure with a front display module and the rear portion including the electronics module including a flexible printed circuit board and an energy storage device.

15. The electronic device of claim 13, wherein the flexible chassis module includes edge structures with each having a channel facing inwardly and being complementarily configured to receive a portion of an outer periphery of the display module.

16. The electronic device of claim 13, wherein the rear portion of the flexible chassis module has a cavity complementarily configured to receive the electronics module.

17. The electronic device of claim 13, further comprising a housing substantially covering the flexible chassis module and electronics module and substantially free from covering the flexible display.

18. The electronic device of claim 13, wherein the flexible chassis module includes edge structures configured to limit angular movement of the flexible chassis module.

19. The electronic device of claim 13, wherein the flexible chassis module includes an unflexed position and a flexed position, the flexible chassis module further includes edge structures each with a stopper structure configured to limit an angular movement of the flexible chassis module when moved to the flexed position.

20. The electronic device of claim 13, wherein the flexible chassis module includes a detent mechanism configured to resist rotation of segments at a specific angle.
